(19) United States
(12) Patent Application Publication
(10) Pub. No.: US 2006/0043602 A1
(43) Pub. Date: Mar. 2, 2006

(54) Flip chip ball grid array package with constraint plate

(76) Inventors: Kuo-Chin Chang, Chia-Yi City (TW); Simon Lu, Hsin-Chu (TW)

Correspondence Address: BIRCH STEWART KOLASCH & BIRCH, PO BOX 747, FALLS CHURCH, VA, 22040-0747, US

(21) Appl. No.: 10/932,005

(22) Filed: Sep. 2, 2004

(51) Int. Cl. H01L 23/48

(52) U.S. Cl. 257/778

(57) ABSTRACT

A flip chip ball grid array package is provided. In one embodiment, a flip chip ball grid array package comprises a substrate having an upper surface and a lower surface opposite the upper surface and a microelectronic element comprising a set of solder balls being secured to the upper surface of the substrate. A constraint member is secured to the lower surface of the substrate so that the constraint member has a degree of rigidity to reduce warpage due to thermal expansion mismatches between at least the microelectronic element and the substrate.

### BACKGROUND

The present invention relates generally to semiconductor chip packages, and more particularly, to a flip chip ball grid array (FCBGA) package having a constraint plate.

Ball grid array (BGA) is an advanced type of integrated circuit packaging technology which is characterized by the use of a substrate whose upper surface is mounted with a semiconductor chip and whose lower surface is mounted with a grid array of solder balls. During a surface mount technology process, for example, the BGA package can be mechanically bonded and electrically coupled to a printed circuit board (PCB) by means of these solder balls.

Flip chip ball grid array is a more advanced type of BGA technology that uses flip chip technology in mounting the active side of the chip in an upside-down manner over the substrate and bonded to the same by means of a plurality of solder bumps attached to input/output pads thereon. Due to the inherent coefficient of thermal expansion mismatches between the FCBGA package components such as for example the chip, substrate, and an underfill (an adhesive flowed between the chip and substrate), high package warpage and thermal stresses are frequently induced in the FCBGA package. These high thermal stresses and warpage not only lead to the delamination in the low-k interconnect layer(s) in the chip, but also cause solder bump cracks leading to failure, degrading the long term operating reliability of the FCBGA package. Furthermore, the substrate onto which the flip chip may be mounted can be a single layer structure, or the substrate may comprise two or many more layers of materials. Often these materials tend to be quite diverse in their composition and structure. The coefficient of thermal expansion for these different layers may be considerably different and may result in uncontrolled bending or thermal induced substrate surface distortions. Such distortions can cause failure of the flip chip or other components of the substrate.

In addition to chip warpage due to thermal effects, chip or substrate warpage may be caused by other steps of the manufacturing process. For example, chip warpage may occur as a consequence of the chip underfill process. Typically, adhesive underfill is applied between the opposing faces of the chip and the underlying substrate to secure the chip to the substrate and to secure the electrical connections, usually solder joints, between the chip and the substrate. When the adhesive underfill is cured or hardened, the cured adhesive tends to shrink placing the solder joints in a compressed state, and often the shrinking adhesive causes warpage of the substrate.

For these reasons and other reasons that will become apparent upon reading the following detailed description, there is a need for an improved FCBGA package that addresses the above-discussed issues.

### SUMMARY

The present invention is directed to flip chip ball grid array packages. In one embodiment, a flip chip ball grid array package comprises a substrate having an upper surface and a lower surface opposite the upper surface and a microelectronic element comprising a set of solder balls being secured to the upper surface of the substrate. A constraint member is secured to the lower surface of the substrate so that the constraint member has a degree of rigidity to reduce warpage due to thermal expansion mismatches between at least the microelectronic element and the substrate.

### BRIEF DESCRIPTION OF THE DRAWINGS

The features, aspects, and advantages of the present invention will become more fully apparent from the following detailed description, appended claims, and accompanying drawings in which:

FIG. 1 is a side view diagram of a semi-finished flip chip ball grid array package according to one embodiment of the present invention.

FIG. 2 shows a bottom view of the semi-finished flip chip ball grid array package of FIG. 1 according to one embodiment of the present invention.

FIG. 3 is a side view diagram of a semi-finished flip chip ball grid array package according to another embodiment of the present invention.

FIG. 4 shows a bottom view of the semi-finished flip chip ball grid array package of FIG. 3 according to one embodiment of the present invention.

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures, materials, and processes have not been described in detail to avoid unnecessarily obscuring the present invention.

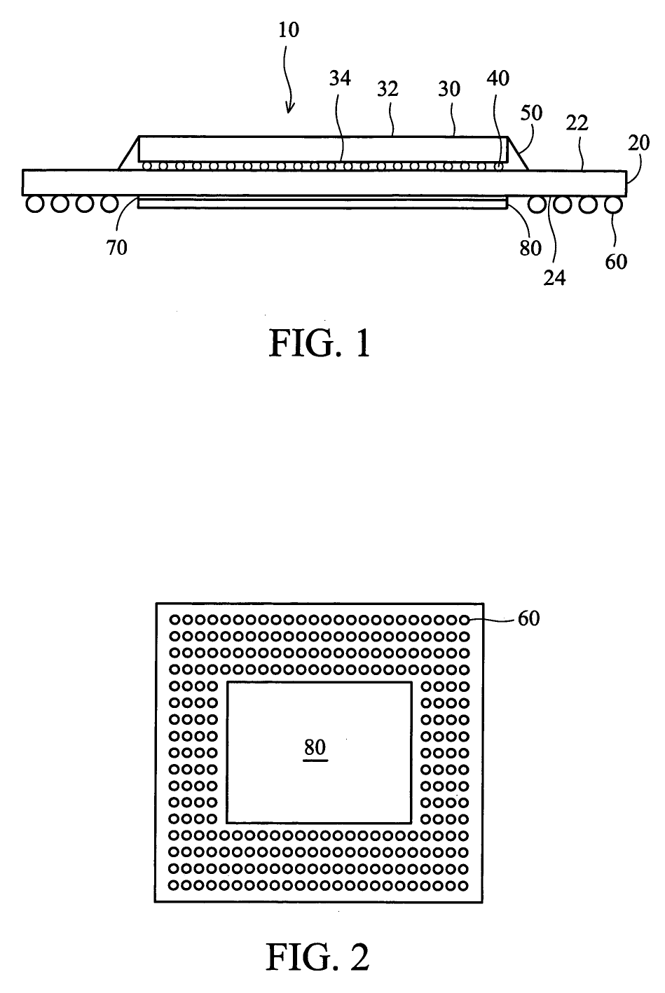

Reference will now be made in detail to the present preferred embodiments of the present invention, examples of which are illustrated in the accompanying drawings. It is understood that FIGS. 1-4 are simplified views showing only the parts related to the present invention; the actual layout of the FCBGA package may be much more complex.

FIG. 1 is a side view diagram of a semi-finished flip chip ball grid array (FCBGA) package 10 according to one embodiment of the present invention. FCBGA package 10 includes a microelectronic element 30 which may be a semiconductor device such as an integrated circuit chip, for example a flip chip. The microelectronic element, hereafter referred to as chip 30, has an upper surface 32 and a lower surface 34 opposite the upper surface 32. A first set of solder balls 40 (or solder bumps) are connected to contact pads (not shown) on the lower surface 34 of chip 30. The combination of the chip 30 and the solder balls 40 are commonly known as and referred to as a flip chip. Chip 30 is secured to a first substrate 20 underlying chip 30. Solder balls 40 are attached to contact pads (not shown) on the upper surface 22 of first substrate 20. First substrate 20 is under filled between chip 30 and substrate 20 by an underfill 50. Underfill 50 has a high tensile modulus that stiffens the FCBGA package 10 to further protect chip 30 from flexural damage. Underfill 50 may be, for example, a commercially available epoxy polymer. A second set of solder balls 60 may be secured to contact pads (not shown) on the lower surface 24 of first substrate 20. The combination of the fist substrate 20 and the second set of solder balls 60 on the lower surface thereof are commonly known as and referred to as a ball grid array. Second set of solder balls 60 may also be secured to contact pads (not shown) on a second substrate (not shown). The second substrate may be a printed wire board (also sometimes called a printed circuit board) or may be a multilayer module known to those skilled in the art.

A constraint member or constraint plate 80 having a degree of rigidity is provided for attaching onto the lower surface 24 of first substrate 20 to protect FCBGA package 10 from flexural damage. Constraint plate 80 reduces the warpage of FCBGA package 10 caused by thermal expansion mismatches between at least the chip 30, first substrate 20, and underfill 50. Constraint plate 80 further reduces the stress inherent in the low-k interconnect layer or layers of chip 30 including at least a passivation layer which coats on the active side of chip 30 protecting the circuits of chip 30 from the environment. By reducing the stress, delamination in the low-k interconnect layer(s) and solder bump cracks may be reduced. FIG. 2 shows a bottom view of the semi-finished flip chip ball grid array package 10 of FIG. 1 showing constraint plate 80 and second set of solder balls 60.

Constraint plate 80 may comprise of one or more layers and preferably provides a sufficient degree of rigidity to first substrate 20 and to the FCBGA package 10. In one embodiment, constraint plate 80 comprises a rigid metal, such as copper. In another embodiment, constraint plate 80 comprises a ceramic material. In yet another embodiment, constraint plate 80 comprises a silicon containing material. However, one skilled in the art will understand that constraint plate 80 may be of any material construction which provides the properties necessary to achieve the objectives of the present invention. An added benefit of mounting constraint plate 80 on the lower surface 24 of first substrate 20 is that depending on the conductive material being used for constraint plate 80, constraint plate 80 may act as a heat sink conducting heat away from chip 30.

Constraint plate 80 has a shape comprising of, for example a rectangle, square, circle, rhombus, ellipse, or polygon but it is understood by those skilled in the art that the shape is dependent on at least the size and shape of first substrate 20. The larger the substrate is, the larger the constraint plate 80 size must be to withstand the package warpage and/or fabrication process. Constraint plate 80 is secured to lower surface 24 of first substrate 20 by an adhesive 70 such as, for example epoxy or tape. Adhesive 70 preferably is chosen to match or accommodate the coefficient of thermal expansion of the constraint plate 80 and the first substrate 20.

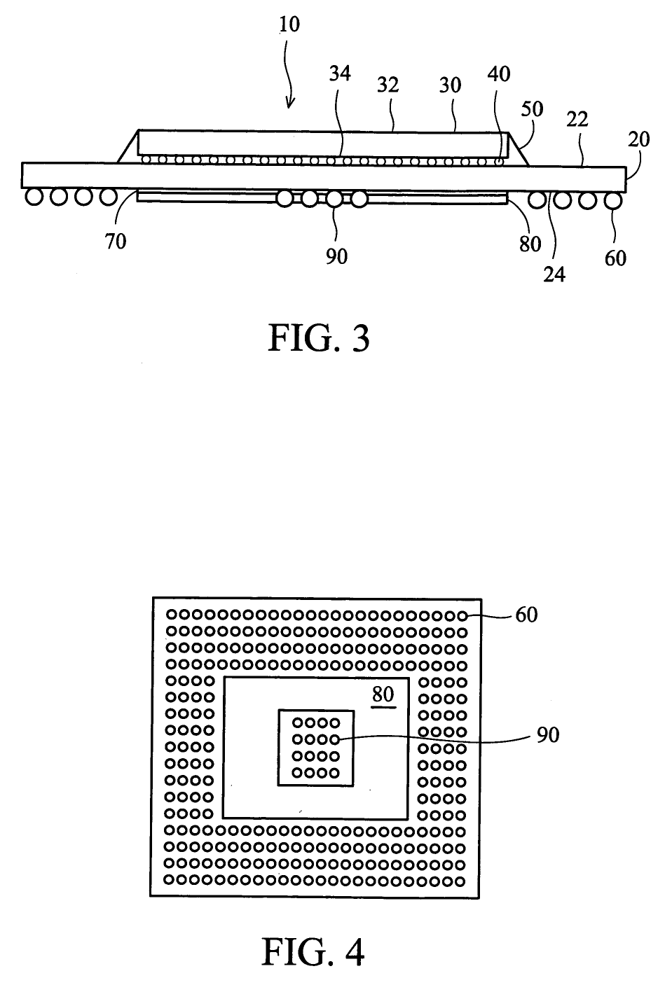

FIG. 3 is a side view diagram of a semi-finished flip chip ball grid array package 10 according to another embodiment of the present invention. FCBGA package 10 is the same as the package depicted in FIG. 1 except with the addition of a set of thermal balls 90 which is secured to the lower surface 24 of first substrate 20. Thermal balls 90 help dissipate heat generated by chip 30. FIG. 4 shows a bottom view of the semi-finished flip chip ball grid array package of FIG. 3.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A flip chip ball grid array package comprising:
a first substrate having an upper surface and a lower surface opposite the upper surface;
a microelectronic element comprising a first set of solder balls being secured to the upper surface of the first substrate; and
a constraint member being secured to the lower surface of the first substrate so that the constraint member has a degree of rigidity to reduce warpage due to thermal expansion mismatches between at least the microelectronic element and the first substrate.

2. The flip chip ball grid array package of claim 1, wherein the first substrate comprises a ball grid array.

3. The flip chip ball grid array package of claim 1, wherein the microelectronic element comprises an integrated circuit chip.

4. The flip chip ball grid array package of claim 3, wherein the microelectronic element comprises a flip chip.

5. The flip chip ball grid array package of claim 1, wherein the first set of solder balls comprises solder bumps.

6. The flip chip ball grid array package of claim 1, further comprising underfill between the microelectronic element and the first substrate.

7. The flip chip ball grid array package of claim 1, wherein the constraint member comprises metal.

8. The flip chip ball grid array package of claim 1, wherein the constraint member comprises ceramic.

9. The flip chip ball grid array package of claim 1, wherein the constraint member comprises silicon.

10. The flip chip ball grid array package of claim 1, wherein the constraint member comprises a material being thermally conductive.

11. The flip chip ball grid array package of claim 1, wherein the constraint member comprises a shape selected from the group consisting of a rectangle, square, circle, rhombus, ellipse, and polygon.

12. The flip chip ball grid array package of claim 1, wherein the constraint member comprises a shape being thermally conductive.

13. The flip chip ball grid array package of claim 1, further comprising an adhesive between the first substrate and the constraint member securing the constraint member to the lower surface of the first substrate.

14. The flip chip ball grid array package of claim 13, wherein the adhesive has a coefficient of thermal expansion that matches the coefficient of thermal expansion of the constraint member and the first substrate.

15. The flip chip ball grid array package of claim 13, wherein the adhesive comprises epoxy.

16. The flip chip ball grid array package of claim 13, wherein the adhesive comprises tape.

17. The flip chip ball grid array package of claim 1 further comprising a set of thermal balls secured to the lower surface of the first substrate for dissipating heat.

18. The flip chip ball grid array package of claim 1, further comprising a second set of solder balls secured to the lower surface of the first substrate, and a second substrate secured to the second set of solder balls.

19. A semiconductor chip package comprising:
a first substrate having an upper surface and a lower surface opposite the upper surface;
a microelectronic element comprising a first set of solder balls being secured to the upper surface of the first substrate; and
a constraint member being secured to the lower surface of the first substrate so that the constraint member has a degree of rigidity to reduce warpage due to thermal expansion mismatches between at least the microelectronic element and the first substrate.

20. The semiconductor chip package of claim 19, wherein the microelectronic element comprises an integrated circuit chip.

21. The semiconductor chip package of claim 20, wherein the microelectronic element comprises a flip chip.

22. The semiconductor chip package of claim 19, further comprising underfill between the microelectronic element and the first substrate.

23. The semiconductor chip package of claim 19, wherein the constraint member comprises metal.

24. The semiconductor chip package of claim 19, wherein the constraint member comprises ceramic.

25. The semiconductor chip package of claim 19, wherein the constraint member comprises silicon.

26. The semiconductor chip package of claim 19, wherein the constraint member comprises a material being thermally conductive.

27. The flip chip ball grid array package of claim 19, wherein the constraint member comprises a shape selected from the group consisting of a rectangle, square, circle, rhombus, ellipse, and polygon.

28. The semiconductor chip package of claim 19, wherein the constraint member comprises a shape being thermally conductive.

29. The semiconductor chip package of claim 19, further comprising an adhesive between the first substrate and the constraint member securing the constraint member to the lower surface of the first substrate.

30. The flip chip ball grid array package of claim 29, wherein the adhesive has a coefficient of thermal expansion that matches the coefficient of thermal expansion of the constraint member and the first substrate.

31. The semiconductor chip package of claim 29, wherein the adhesive comprises epoxy.

32. The flip chip ball grid array package of claim 29, wherein the adhesive comprises tape.

33. The semiconductor chip package of claim 19 further comprising a set of thermal balls secured to the lower surface of the first substrate for dissipating heat.

34. The flip chip ball grid array package of claim 19, further comprising a second set of solder balls secured to the lower surface of the first substrate, and a second substrate secured to the second set of solder balls.
